(19) United States
(12) Patent Application Publication
(10) Pub. No.: US 2021/0185827 A1
(43) Pub. Date: Jun. 17, 2021

(54) PRINTING CONDUCTIVE TRACES

(71) Applicant: HEWLETT-PACKARD DEVELOPMENT COMPANY, L.P., Spring, TX (US)

(72) Inventors: Jarrid WITTKOPF, Palo Alto, CA (US); Ning GE, Palo Alto, CA (US); Robert IONESCU, Palo Alto, CA (US); Helen A. HOLDER, Palo Alto, CA (US)

(73) Assignee: HEWLETT-PACKARD DEVELOPMENT COMPANY, L.P., Houston, TX (US)

(21) Appl. No.: 16/076,706

(22) PCT Filed: Feb. 8, 2017
(86) PCT No.: PCT/US2017/016875

§ 371 Date: Aug. 9, 2018

(51) Int. Cl. H05K 3/24; H05K 1/03; H05K 3/12; H05K 3/28

(52) U.S. Cl. CPC H05K 3/246; H05K 1/0386; H05K 2201/10098; H05K 3/28; H05K 3/125

(57) ABSTRACT

In an example implementation, a conductive trace printing system includes a conductive trace application station to apply a conductive trace onto a media substrate. The printing system also includes a conductive trace enhancement station to expose the conductive trace to an electroless metal plating solution to generate an enhanced conductive trace.

### BACKGROUND

Many retailers, manufacturers, and distributers want access to cost effective RFID (radio frequency identification) tags to put on all of their products. Incorporating RFIDs onto product packaging can help provide product security, reduce the number of lost products, and collect data to indicate trends in the movement and sales of products. RFID technology allows for multiple products to be scanned and accounted for quickly, and at the same time. RFIDs are being implemented in an increasing variety of products due to their decreasing cost. For many products, however, the cost threshold for using RFIDs remains too high.

### BRIEF DESCRIPTION OF THE DRAWINGS

Examples will now be described with reference to the accompanying drawings, in which:

FIG. 1 shows an example of a conductive trace printing system that is suitable for generating high quality metal conductive traces on media substrates through the enhancement of printed conductive traces in an electroless metal plating process;

FIG. 2 shows an example of a conductive trace printing system with additional details of a conductive trace application station and a conductive trace enhancement station;

FIG. 3 shows a blow-up block diagram of an example conductive trace application station illustrating different example print engines suitable for implementing within a conductive trace application station;

FIG. 4 shows an example of a conductive trace printing system that includes an example overprint application station;

FIG. 5 shows examples of media substrates in various stages of having a conductive trace applied by a conductive trace printing system;

FIGS. 6 and 7 are flow diagrams showing example methods 600 and 700, of applying a conductive trace to a media substrate.

Throughout the drawings, identical reference numbers designate similar, but not necessarily identical, elements.

### DETAILED DESCRIPTION

A significant challenge to the adoption of RFIDs is their cost, which varies depending on the type of RFID being used. Active RFIDs have battery power and can broadcast their own signals, act as beacons to track product locations in real-time, and provide much longer read times than passive RFIDs, but they are much more expensive than passive RFIDs. Passive RFIDs are cheaper, but they have no internal power source and rely on energy from the RFID reader to function. Passive RFIDs are therefore used in less demanding applications such supply chain management, smart labels for packaging, access control, and so on.

Further still, passive RFIDs can be chipped or chipless, which also impacts their cost. The added cost to design and fabricate a microchip for passive RFIDs can make passive RFIDs too expensive for use in many low cost and low margin products. Passive chipless RFIDs are therefore the cheapest, and they are increasingly being used in low end products. However, both chipped and chipless RFID tags are mainly generated through screen printing of conductive metal particles or adhesion of conductive metal foils. These methods of fabricating passive RFIDs are cost intensive, difficult to scale, and involve additional processing steps. With these methods, passive RFIDs often have to be produced off the product and then adhered later in a subsequent step.

Accordingly, examples of systems and methods described herein enable the generation of high quality metal conductive traces, such as metal coil RFID tags (RFIDs), through an electroless metal plating enhancement to printed conductive traces. The production process enables the generation of high quality, low cost RFIDs and other conductive traces directly onto packaging material substrates. In some examples, a protective overprint layer can be applied to the RFIDs to enhance their durability.

In an example process, a conductive trace design such as a passive chipless RFID design, can be printed on the surface of a media substrate (e.g., a package substrate) using different printing technologies such as inkjet and liquid electro-photographic (LEP) printing processes. Because the conductive metal trace can have impurities and/or contaminants, its conductivity may be attenuated and it may not be sufficiently conductive to be used as an RFID directly, for example. Therefore, the conductive trace can be exposed to an electroless metal plating solution to enhance the trace through electroless deposition of metal, such as copper, onto the trace. During exposure to the metal plating solution, reactants within the solution will reduce onto the conductive trace and generate, for example, a high quality metal-plated passive chipless RFID.

Exposure of the conductive trace to the metal plating solution can be achieved by various methods including through the use of a saturated sponge-like material or through a sealed liquid bath. The method of exposing the trace to the metal plating solution can depend in part on the type of media substrate on which the trace is printed. For example, while the use of a liquid bath may work faster and reduce issues with transporting reactants, it may be less suitable for use with a paper substrate due to the potential for over-saturating the substrate. Delivering the plating solution through a saturated sponge may take longer, but it may also provide better control over the amount of liquid introduced to the substrate.

In a particular example, a conductive trace printing system includes a conductive trace application station to apply a conductive trace onto a media substrate. The printing system also includes a conductive trace enhancement station to expose the conductive trace to an electroless metal plating solution to generate an enhanced conductive trace.

In another example, a non-transitory machine-readable storage medium stores instructions that when executed by a processor of a conductive trace printing system, cause the system to apply a conductive trace to a media substrate, and then expose the conductive trace to an electroless metal plating solution to enhance the conductive trace. In some examples, an insulating layer can be applied to the media substrate prior to applying the conductive trace, and the conductive trace can be applied on the insulating layer.

In another example, a conductive trace printing system includes a printing device to print a preliminary conductive trace onto a media substrate, and a solution applicator to expose the preliminary conductive trace to an electroless metal plating solution to generate an enhanced conductive trace. The printing system also includes a memory device comprising print instructions and print data, and a processor programmed to execute the print instructions to control the printing device to print the preliminary conductive trace in a pattern according to information in the print data.

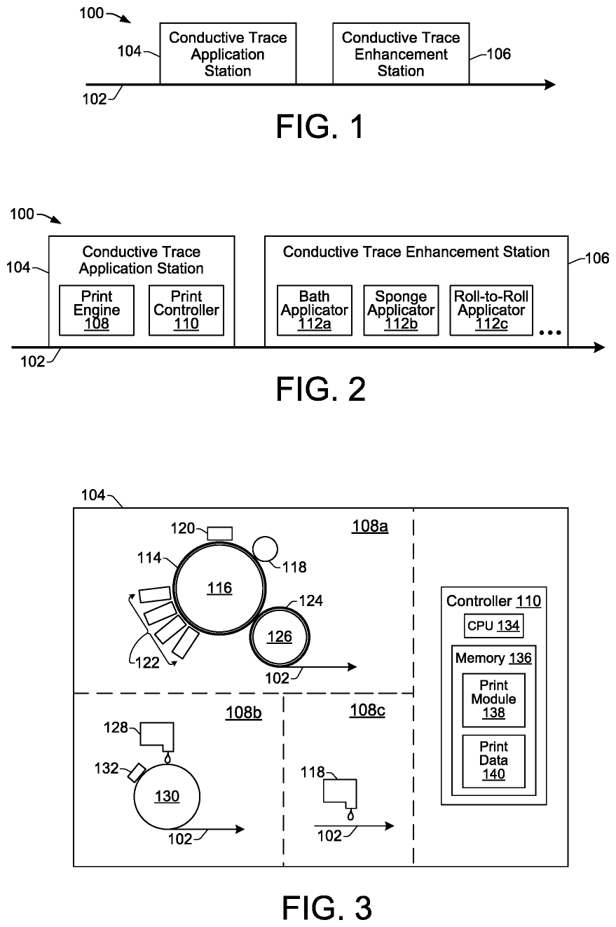

FIG. 1 shows an example of a conductive trace printing system 100 that is suitable for generating high quality metal conductive traces on media substrates through the enhancement of printed conductive traces in an electroless metal plating process. As shown in FIG. 1, a media substrate 102 can travel through the printing system 100 in a direction taking it from a conductive trace application station 104 to a conductive trace enhancement station 106. A media substrate 102 can include a variety of printable media substrates such as substrates used in product packaging. Examples of media substrates 102 include, but are not limited to, various plastics such as polyolefin, polyester, polyethylene terephthalate, and polyvinyl chloride; papers such as kraft paper, sulfite paper, and greaseproof paper; and, single and multi-layer paperboards such as white board, solid board, chipboard, fiberboard, and corrugated cardboard.

As the media substrate 102 passes through the conductive trace application station 104, a preliminary conductive trace can be applied to the substrate 102. The conductive trace can be applied, for example, as a nickel (Ni) trace or an iron (Fe) trace, or as a trace comprising another metal. The conductive trace can be applied in any design to achieve a conductive purpose, such as in the design of an RFID tag. After the conductive trace is applied to the media substrate 102 the substrate 102 passes through the conductive trace enhancement station 106. As the conductive trace passes through the conductive trace enhancement station 106, it is exposed to an electroless metal plating solution such as a copper solution (e.g., CuSO4 in acidic, basic, or neutral environments). During exposure to the metal plating solution, a process of electroless deposition of metal onto the conductive trace is driven by reactants within the metal plating solution. The metal deposited onto the conductive trace from the metal plating solution is generally spontaneous with a metal of higher nobility than the metal comprising the conductive trace. The use of a reducing agent in the electroless plating solution is needed if the metal in the plating solution is lower or around the same nobility as the conductive trace metal. Examples of reducing agents can include sodium hypophosphite, sodium borohydride, hydrazine, and so on. Deposition of additional metal onto the conductive trace generates an enhanced conductive trace that has improved conductivity compared to that of the preliminary conductive trace applied by the conductive trace application station 104.

FIG. 2 shows an example of a conductive trace printing system 100 with additional details of a conductive trace application station 104 and a conductive trace enhancement station 106. As shown in FIG. 2, a conductive trace application station 104 can include a print engine 108 and a print controller 110, while a conductive trace enhancement station 106 can include or be implemented as a variety of different metal plating solution applicators 112 (illustrated as applicators 112a, 112b, 112c). FIG. 3 shows a blow-up block diagram of an example conductive trace application station 104 illustrating different examples of print engines 108 (illustrated as print engines 108a, 108b, 108c) suitable for implementing within the conductive trace application station 104. FIG. 3 additionally shows an example print controller 110 for controlling a print engine 108 to print a conductive trace onto a media substrate 102.

Referring generally to FIGS. 2 and 3, one example of a suitable print engine 108 for implementation within a conductive trace application station 104 comprises a liquid electro-photographic (LEP) printer 108a. The LEP printer 108a shown in FIG. 3 is a partial illustration of an LEP printer intended to supplement the following brief description of how an LEP printer can function to print a conductive trace onto a media substrate 102. An LEP printer 108a can receive a printable media substrate 102 in various forms including cut-sheet paper from a stacked media input mechanism (not shown) or a media web from a media paper roll input mechanism (not shown). An LEP printer 108a includes a photo imaging component, or photoreceptor 114, sometimes referred to as a photo imaging plate (PIP). The photoreceptor 114 is mounted on a drum or imaging cylinder 116, and it defines the outer surface of the imaging cylinder 116 on which images can be formed. In some examples, images comprise designs and patterns for conductive traces. A charging component such as charge roller 118 generates electrical charge that flows toward the photoreceptor surface and covers it with a uniform electrostatic charge. A laser imaging unit 120 exposes image areas on the photoreceptor 114 by dissipating (neutralizing) the charge in those areas.

Exposure of the photoreceptor 114 creates a ‘latent image’ in the form of an invisible electrostatic charge pattern that replicates the conductive trace or other image to be printed. After the latent/electrostatic conductive trace image is formed on the photoreceptor 114, it is developed by a binary ink development (BID) roller 122 to form a conductive ink image on the outer surface of the photoreceptor 114. As noted above, the conductive trace can be applied using a variety of different conductive materials. Examples of conductive materials are metal materials that can include nickel (Ni), iron (Fe) trace, and others. In general, there is a wide range of materials that can be used for conductive inks. Examples of these material can include metal-based materials, carbon-based materials such as graphite and carbon nanotubes, and nanoparticles of metals.

In general, each BID roller 122 develops a single ink component or color (i.e., a single color separation) of the image, and each developed ink component separation corresponds with one image impression. The four BID rollers 122 shown, indicate a four component process, such as a four color process (i.e., C, M, Y, and K). In the present example, the four BID rollers 122 can include a conductive ink formulation for developing a conductive trace. The four BID rollers 122 may additionally include insulator and/or dielectric material ink formulations to be developed onto the photoreceptor 114, as well as other material ink formulations associated with the application of a conductive trace onto a media substrate 102. In some examples, an LEP printer can include additional BID rollers 122 corresponding to additional ink colors and/or ink formulations.

After a single ink component separation impression of an image is developed onto the photoreceptor 114, it is electrically transferred from the photoreceptor 114 to an image transfer blanket 124, which is electrically charged through an intermediate drum or transfer roller 126. The image transfer blanket 124 overlies, and is securely attached to, the outer surface of the transfer roller 126. The transfer roller 126 is can heat the blanket 124, which causes the liquid in the ink to evaporate and the solid particles to partially melt and blend together, forming a hot adhesive liquid plastic that can be transferred to a print media substrate 102.

In other examples, a conductive trace application station 104 may implement an inkjet based print engine 108 (108b, 108c) to apply a conductive trace to a media substrate 102 using an inkjet printhead 128. An inkjet based print engine enables a drop-on-demand construction of a conductive trace onto a transfer roller 130 as shown with inkjet print engine 108b, or directly onto a media substrate 102 as shown with inkjet print engine 108c. A conductive ink trace applied to a transfer roller 130 may be exposed to heat or other radiation from a heat/radiation device 132 to help cure the ink prior to transferring to conductive trace onto a media substrate 102. When applied directly to a media substrate, as shown with inkjet print engine 108c, a conductive ink trace may be exposed to heat or another curing or drying mechanism in a subsequent step (not shown). Various formulations of jettable conductive inks may include nickel (Ni), iron (Fe) trace, and others. As noted above, various materials can be used for conductive inks such as metal-based materials, carbon-based materials such as graphite and carbon nanotubes, and nanoparticles of metals.

An example print controller 110 enables control over the printing and patterning of conductive traces and other images generated by a print engine 108. The controller 110 can also control various other operations of the conductive trace printing system 100 to facilitate the application and enhancement of a patterned conductive trace, such as an RFID tag, onto a media substrate 102. As shown in FIG. 3, an example controller 110 can include a processor (CPU) 134 and a memory 136. The controller 110 may additionally include other electronics (not shown) for communicating with and controlling various components of the conductive trace printing system 100. Such other electronics can include, for example, discrete electronic components and/or an ASIC (application specific integrated circuit). Memory 136 can include both volatile (i.e., RAM) and nonvolatile memory components (e.g., ROM, hard disk, optical disc, CD-ROM, magnetic tape, flash memory, etc.). The components of memory 136 can comprise non-transitory, machine-readable (e.g., computer/processor-readable) media that can provide for the storage of machine-readable coded program instructions, data structures, program instruction modules, PDL (page description language), PCL (printer control language), JDF (job definition format), 3MF formatted data, and other data and/or instructions executable by a processor 134 of the conductive trace printing system 100.

An example of executable instructions to be stored in memory 136 include instructions associated with a print module 138, while examples of stored data can include print data 140. In general, print module 138 can include programming instructions executable by processor 134 to cause the print engine 108 to apply a conductive trace to a media substrate 102 according to information defined within print data 140 by any of several printing techniques as discussed above with regard to example print engines 108a, 108b, and 108c. Print data 140 can include information about patterns and/or designs of conductive traces such as RFIDS, in addition to text and other images to be printed on a media substrate 102.

Referring again to FIG. 2, as mentioned, a conductive trace enhancement station 106 can include or be implemented as a variety of different metal plating solution applicators 112 (illustrated as applicators 112a, 112b, 112c). In one example, a metal plating solution applicator 112 can comprise a sponge applicator 112a capable of absorbing metal plating solution and distributing it onto a preliminary conductive trace applied to a media substrate 102 by the conductive trace application station 104. A sponge applicator 112a can be formed of a variety of sponge materials including cellulose wood fibers or foamed plastic polymers. In some examples, a metal plating solution applicator 112 can comprise a liquid bath applicator 112b capable of soaking a conductive trace in a bath of metal plating solution as the media substrate 102 passes the conductive trace enhancement station 106. Various other types of metal plating solution applicators are possible and contemplated herein, including a roll-to-roll applicator, and others. As noted above, the type of applicator 112 used to expose the conductive trace to the metal plating solution can depend in part on the type of media substrate 102 on which the trace is printed.

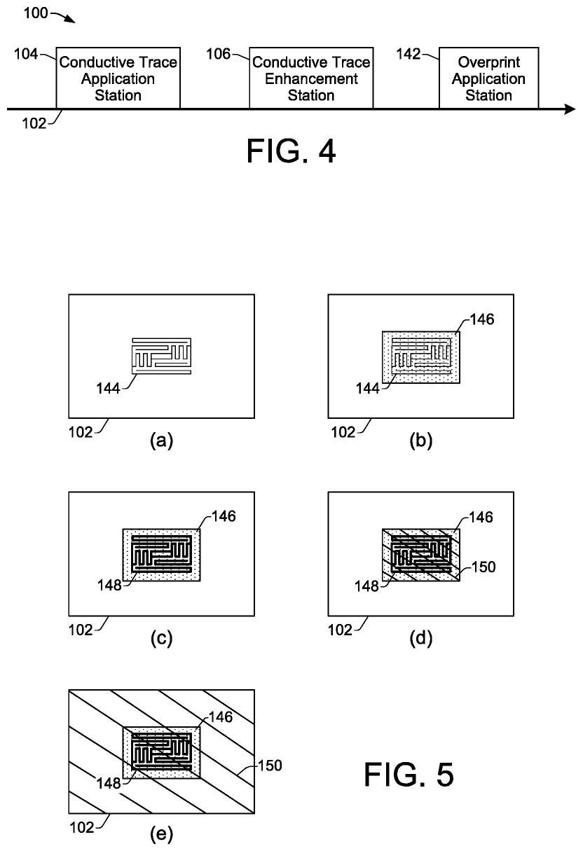

FIG. 4 shows an example of a conductive trace printing system 100 that includes an example overprint application station 142. In some examples of a conductive trace printing system 100, an overprint application station 142 can apply a protective overprint layer to a conductive trace and/or to the full surface of a media substrate 102. An overprint application station 142 can be implemented by any of a variety of coating application devices including, for example, flexographic coating devices, gravure coating devices, reverse roll coating devices, knife-over-roll coating (“gap coating”) devices, metering rod (meyer rod) coating devices, slot die (slot, extrusion) coating devices, immersion coating devices, curtain coating devices, and air-knife coating devices. An overprint layer can include various transparent or opaque protective coatings such as OPV (over print varnish) coatings, UV coatings with matte or gloss finishes, electrically insulating coatings, dielectric coatings, aqueous coatings, and so on. Such coatings can be applied to conductive traces on media substrates 102 and/or to the entire surface of media substrates 102. Such overprint layers can help protect conductive traces such as RFIDs applied to a media substrate 102, as well as help protect, enhance, and strengthen the media substrate itself.

FIG. 5 shows examples of media substrates 102 in various stages of having a conductive trace applied by a conductive trace printing system 100. As shown in part (a) of FIG. 5, a media substrate 102 has had a preliminary conductive trace 144 applied at the conductive trace application station 104. In some examples, as shown in part (b) of FIG. 5, prior to applying a preliminary conductive trace 144, an insulating layer 146 can be applied to the media substrate 102 by the conductive trace application station 104. In these examples, the preliminary conductive trace 144 can be applied to the insulating layer 146 instead of directly to the surface of the media substrate 102. As shown in part (c) of FIG. 5, a the preliminary conductive trace 144 has been exposed to an electroless metal plating solution in the conductive trace enhancement station 106 to generate an enhanced conductive trace 148. An enhanced conductive trace 148 can include additional metal material formed on the trace making it thicker and more highly conductive. As shown in part (d) of FIG. 5, a protective overprint layer 150 has been applied by the overprint application station 142 over the enhanced conductive trace 148. As shown in part (e) of FIG. 5, a protective overprint layer 150 has been applied over the entire surface of the media substrate 102, including the enhanced conductive trace 148.

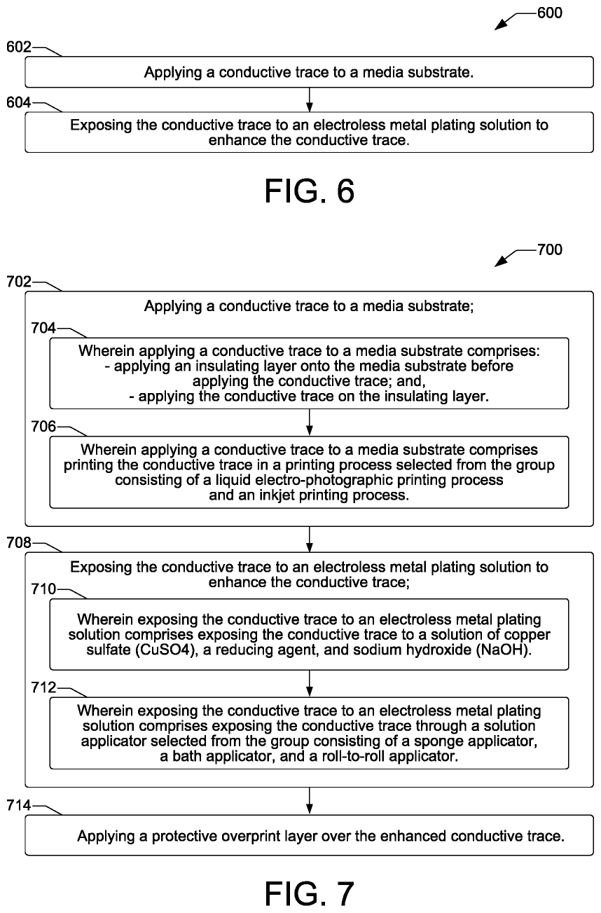

FIGS. 6 and 7 are flow diagrams showing example methods 600 and 700, of applying a conductive trace to a media substrate. Methods 600 and 700 are associated with examples discussed above with regard to FIGS. 1-5, and details of the operations shown in methods 600 and 700 can be found in the related discussion of such examples. The operations of methods 600 and 700 may be embodied as programming instructions stored on a non-transitory, machine-readable (e.g., computer/processor-readable) medium, such as memory 136 shown in FIG. 3. In some examples, implementing the operations of methods 600 and 700 can be achieved by a processor, such as a processor 134 of FIG. 3, reading and executing the programming instructions stored in a memory 136. In some examples, implementing the operations of methods 600 and 700 can be achieved using an ASIC and/or other hardware components alone or in combination with programming instructions executable by a processor 134.

The methods 600 and 700 may include more than one implementation, and different implementations of methods 600 and 700 may not employ every operation presented in the flow diagrams of FIGS. 6 and 7. Therefore, while the operations of methods 600 and 700 are presented in a particular order, the order of their presentation is not intended to be a limitation as to the order in which the operations may actually be implemented, or as to whether all of the operations may be implemented. For example, one implementation of method 700 might be achieved through the performance of a number of initial operations, without performing one or more subsequent operations, while another implementation of method 700 might be achieved through the performance of all of the operations.

Referring now to the flow diagram of FIG. 6, an example method 600 of applying a conductive trace to a media substrate begins an block 602 with applying a conductive trace to a media substrate. The method 600 also includes exposing the conductive trace to an electroless metal plating solution to enhance the conductive trace, as shown at block 604.

Referring to the flow diagram of FIG. 7, another example method 700 of applying a conductive trace to a media substrate begins an block 702 with applying a conductive trace to a media substrate. In some examples, as shown at block 704, applying a conductive trace to a media substrate can include applying an insulating layer onto the media substrate before applying the conductive trace, and then applying the conductive trace on the insulating layer. In some examples, applying a conductive trace to a media substrate can include printing the conductive trace in a printing process selected from the group consisting of a liquid electro-photographic printing process and an inkjet printing process, as shown at block 706.

The method 700 can continue at block 708 with exposing the conductive trace to an electroless metal plating solution to enhance the conductive trace. In some examples, as shown at block 710, exposing the conductive trace to an electroless metal plating solution comprises exposing the conductive trace to a solution of copper sulfate (CuSO4), a reducing agent, and sodium hydroxide (NaOH). In some examples, exposing the conductive trace to an electroless metal plating solution comprises exposing the conductive trace through a solution applicator selected from the group consisting of a sponge applicator, a bath applicator, and a roll-to-roll applicator, as shown at block 712. The method 700 can continue as shown at block 714, with applying a protective overprint layer over the enhanced conductive trace.

What is claimed is:

1. A conductive trace printing system comprising:
a conductive trace application station to apply a conductive trace onto a media substrate; and,
a conductive trace enhancement station to expose the conductive trace to an electroless metal plating solution to generate an enhanced conductive trace.

2. A printing system as in claim 1, wherein the conductive trace application station comprises a liquid electro-photographic device to develop the conductive trace onto a charged roller, transfer the conductive trace to a transfer roller, and transfer the conductive trace from the transfer roller to the media substrate.

3. A printing system as in claim 1, wherein the conductive trace application station comprises a fluid jetting device to jet a conductive trace solution onto a transfer roller to be transferred to the media substrate.

4. A printing system as in claim 1, wherein the conductive trace enhancement station comprises a solution applicator selected from the group consisting of a sponge applicator, a liquid bath applicator, and a roll-to-roll applicator.

5. A printing system as in claim 1, further comprising an overprint layer station to apply a protective overprint layer over the enhanced conductive trace.

6. A printing system as in claim 5, wherein the overprint layer station comprises a coating device selected from the group consisting of a flexography coating device, a gravure coating device, a reverse-roll coating device, a knife-over-roll coating device, a Meyer rod coating device, a slot die coating device, an immersion coating device, a curtain coating device, and an air-knife coating device.

7. A printing system as in claim 1, wherein:
the conductive trace comprises a metal having a first nobility; and,
the metal plating solution comprises a metal having a second nobility, wherein the second nobility is greater than the first nobility.

8. A non-transitory machine-readable storage medium storing instructions that when executed by a processor of a conductive trace printing system cause the system to:
apply a conductive trace to a media substrate; and,
expose the conductive trace to an electroless metal plating solution to enhance the conductive trace.

9. A medium as in claim 8, wherein applying a conductive trace to a media substrate comprises:
applying an insulating layer onto the media substrate before applying the conductive trace; and,
applying the conductive trace on the insulating layer.

10. A medium as in claim 8, wherein applying a conductive trace to a media substrate comprises printing the conductive trace in a printing process selected from the group consisting of a liquid electro-photographic printing process and an inkjet printing process.

11. A medium as in claim 8, wherein exposing the conductive trace to an electroless metal plating solution comprises exposing the conductive trace to a solution of copper sulfate (CuSO4), a reducing agent, and sodium hydroxide (NaOH).

12. A medium as in claim 8, wherein exposing the conductive trace to an electroless metal plating solution comprises exposing the conductive trace through a solution applicator selected from the group consisting of a sponge applicator, a bath applicator, and a roll-to-roll applicator.

13. A medium as in claim 8, the instructions further causing the system to apply a protective overprint layer over the enhanced conductive trace.

14. A conductive trace printing system comprising:
a printing device to print a preliminary conductive trace onto a media substrate;
a solution applicator to expose the preliminary conductive trace to an electroless metal plating solution to generate an enhanced conductive trace;
a memory device comprising print instructions and print data; and,
a processor programmed to execute the print instructions to control the printing device to print the preliminary conductive trace in a pattern according to information in the print data.

15. A printing system as in claim 14, wherein the pattern of the preliminary conductive trace comprises an RFID tag.
